(19) United States
(12) Patent Application Publication
(10) Pub. No.: US 2026/0013230 A1
(43) Pub. Date: Jan. 8, 2026

(54) PIXEL ARRAY SUBSTRATE AND DISPLAY PANEL

(71) Applicant: E Ink Holdings Inc., HSINCHU (TW)

(72) Inventors: Chin-Hsien CHOU, HSINCHU (TW); Chi-Ming WU, HSINCHU (TW); Wen-Ya CHAO, HSINCHU (TW); Kuang-Heng LIANG, HSINCHU (TW)

(21) Appl. No.: 19/232,897

(22) Filed: Jun. 10, 2025

(30) Foreign Application Priority Data
Jul. 5, 2024 (TW) 113125391

(51) Int. Cl. H10D 86/40; G02F 1/1362; G02F 1/167; G02F 1/16766; G02F 1/1685; G09G 3/34; G09G 3/36; H10D 86/60

(52) U.S. Cl. CPC H10D 86/441; G02F 1/136213; G02F 1/136286; G02F 1/167; G02F 1/16766; G02F 1/1685; G09G 3/344; G09G 3/3655; H10D 86/481; H10D 86/60; G09G 2300/0426; G09G 2300/0814; G09G 2300/0842

(57) ABSTRACT

A pixel array substrate includes pixel circuits placed at a display area, first conductive lines placed at a first peripheral region, second conductive lines placed at a second peripheral region, and pairs of scan lines including a first scan line and a second scan line apiece. The first scan line is connected to the first conductive line, and extends to the display area for connecting a first pixel column. The second scan line is connected to the second conductive line, and extends to the display area for connecting a second pixel column. A sum of the number of cross-capacitances formed by the first scan line crossing the first conductive lines and the number of cross-capacitances formed by the second scan line crossing the second conductive lines are the number of total cross-capacitances, and the number of total cross-capacitances is the same for each pair of scan lines.

### RELATED APPLICATIONS

This application claims priority to Taiwan Application Serial Number 113125391, filed Jul. 5, 2024, which is herein incorporated by reference.

### BACKGROUND

### Technical Field

The disclosure relates to a pixel array substrate and a display panel.

### Description of Related Art

With the rapid development of display technology, the narrowed design of the display border makes it possible to increase the screen-to-body ratio of the display device, thus obtaining a larger display area in a limited display volume. However, in a circuit layout with narrow border or borderless requirements, the capacitive coupling effect between scanning signal lines may cause transmitted signals to interfere with each other, even affecting the brightness and quality of the display.

### SUMMARY

Therefore, the disclosure provides a pixel array substrate. The pixel array substrate has a display area, a first peripheral region, and a second peripheral region. The first peripheral region and the second peripheral region are located at two sides of the display area, and the pixel array substrate includes pixel circuits, first conductive lines, second conductive lines, and multiple pairs of scan lines. The first conductive lines are placed at the first peripheral region. The second conductive lines are placed at the second peripheral region. Each of the pairs of scan lines includes a first scan line and a second scan line. The first scan line is electrically connected to a corresponding one of the first conductive lines through a first node, and extending to the display area from the first node for connecting a first pixel column of the pixel columns. The second scan line is electrically connected to a corresponding one of the second conductive line through a second node, and extending to the display area from the second node for connecting a second pixel column of the pixel columns. A sum of the number of cross-capacitances formed by the first scan line crossing the first conductive lines and the number of cross-capacitances formed by the second scan line crossing the second conductive lines are the number of total cross-capacitances, and the number of the total cross-capacitances is the same for each of the pairs of scan lines.

According to an embodiment of the disclosure, the display area has a first display block and a second display block, the pixel circuits are placed at the first display block and the second display block, and the pixel array substrate further includes a first block selection line and a second block selection line. The first block selection line is placed at the first peripheral region and corresponds to the first display block. The first block selection line is electrically connected to the pixel circuits which are placed at the first display block. The second block selection line is placed at the second peripheral region and corresponds to the second display block. The second block selection line is electrically connected to the pixel circuits which are placed at the second display block.

According to an embodiment of the disclosure, one of the pixel circuits is electrically connected to the first scan line or the second scan line of one of the pairs of scan lines, one of the first block selection line and the second block selection line, and a data line.

According to an embodiment of the disclosure, the one of the pixel circuits includes an AND gate circuit and a pixel electrode. The AND gate circuit includes a first transistor and a second transistor. A first terminal of the first transistor is electrically connected to one of the first block selection line and the second block selection line, and a second terminal of the first transistor is electrically connected to the data line. A first terminal of the second transistor is electrically connected to the first scan line or the second scan line of the one of the pairs of scan lines, and a second terminal of the second transistor is electrically connected to a third terminal of the first transistor. The pixel electrode is electrically connected to a third terminal of the second transistor.

According to an embodiment of the disclosure, the first peripheral region and the second peripheral region are located on opposite sides of the display area.

According to an embodiment of the disclosure, the first scan line and the second scan line of the pairs of scan lines are interleaved with each other.

According to an embodiment of the disclosure, the number of cross-capacitances formed by the first scan line crossing the first conductive lines of the first one of the pairs of scan lines to the number of cross-capacitances formed by the first scan line crossing the first conductive lines of the last one of the pairs of scan lines are in an ascending order.

According to an embodiment of the disclosure, the number of cross-capacitances formed by the second scan line crossing the second conductive lines of the first one of the pairs of scan lines to the number of cross-capacitances formed by the second scan line crossing the second conductive lines of the last one of the pairs of scan lines are in a descending order.

The disclosure provides a display panel. The display panel includes a pixel array substrate, an opposite substrate, and a display medium layer. The pixel array substrate has a display area, a first peripheral region, and a second peripheral region. The first peripheral region and the second peripheral region are located at two sides of the display area, and the pixel array substrate includes pixel circuits, first conductive lines, second conductive lines, and multiple pairs of scan lines. The first conductive lines are placed at the first peripheral region. The second conductive lines are placed at the second peripheral region. Each of the pairs of scan lines includes a first scan line and a second scan line. The first scan line is electrically connected to a corresponding one of the first conductive lines through a first node, and extending to the display area from the first node for connecting a first pixel column of the pixel columns. The second scan line is electrically connected to a corresponding one of the second conductive line through a second node, and extending to the display area from the second node for connecting a second pixel column of the pixel columns. A sum of the number of cross-capacitances formed by the first scan line crossing the first conductive lines and the number of cross-capacitances formed by the second scan line crossing the second conductive lines are the number of total cross-capacitances, and the number of the total cross-capacitances is the same for each of the pairs of scan lines. The display medium layer is placed between the pixel array substrate and the opposite substrate.

According to an embodiment of the disclosure, the display medium layer is an electrophoretic display material layer.

According to an embodiment of the disclosure, the display medium layer is a liquid crystal material layer.

According to an embodiment of the disclosure, the display area has a first display block and a second display block, the pixel circuits are placed at the first display block and the second display block, and the pixel array substrate further includes a first block selection line and a second block selection line. The first block selection line is placed at the first peripheral region and corresponds to the first display block. The first block selection line is electrically connected to the pixel circuits which are placed at the first display block. The second block selection line is placed at the second peripheral region and corresponds to the second display block. The second block selection line is electrically connected to the pixel circuits which are placed at the second display block.

According to an embodiment of the disclosure, each of the pixel circuits includes an AND gate circuit and a pixel electrode. The AND gate circuit includes a first transistor and a second transistor. A first terminal of the first transistor is electrically connected to one of the first block selection line and the second block selection line, and a second terminal of the first transistor is electrically connected to the data line. A first terminal of the second transistor is electrically connected to the first scan line or the second scan line of the one of the pairs of scan lines, and a second terminal of the second transistor is electrically connected to a third terminal of the first transistor. The pixel electrode is electrically connected to a third terminal of the second transistor.

According to an embodiment of the disclosure, each of the pixel circuits further includes a storage capacitance and a pixel capacitance. A first terminal of the storage capacitance connects the pixel electrode, and a second terminal of the storage capacitance connects a first common electrode. A first terminal of the pixel capacitance connects a second common electrode, and a second terminal of the pixel capacitance connects the pixel electrode.

According to an embodiment of the disclosure, the first common electrode is a common reference voltage for the pixel array substrate, and the second common electrode is a common reference voltage for the opposite substrate.

According to an embodiment of the disclosure, the first scan line and the second scan line of the pairs of scan lines are interleaved with each other.

### BRIEF DESCRIPTION OF THE DRAWINGS

In order to make the above and other features, advantages and embodiments of the disclosure easier to understand, the accompanying drawings are described as follows.

FIG. 1 is a schematic diagram showing a display panel in accordance with an embodiment of the present disclosure.

FIG. 2 is a schematic diagram showing a pixel array substrate in accordance with an embodiment of the present disclosure.

FIG. 3 is an enlarged schematic diagram showing first conductive lines and first scan lines at the first peripheral region in accordance with an embodiment of the present disclosure.

FIG. 4 is a schematic diagram showing a pixel array substrate having several display blocks in accordance with an embodiment of the present disclosure.

FIG. 5 is a schematic diagram showing a pixel circuit in accordance with an embodiment of the present disclosure.

### DETAILED DESCRIPTION

The following disclosure provides many different embodiments, or examples, for implementing different features of the provided subject matter. Embodiments of components and arrangements described below are merely examples and are not intended to be limiting. In addition, the present disclosure may repeat reference numerals and/or letters in the various examples for the purpose of simplicity and clarity and does not in itself dictate a relationship between the various embodiments and/or configurations discussed.

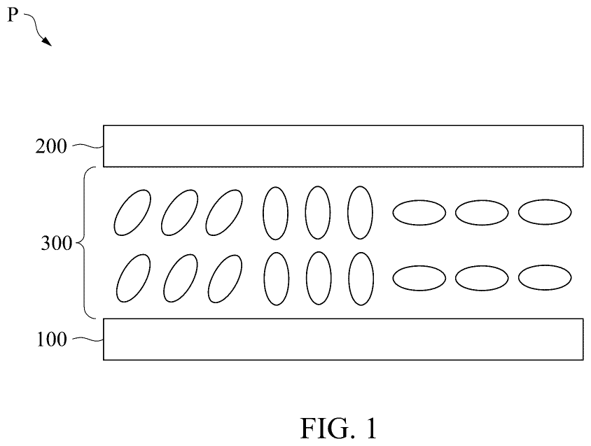

Reference is made to FIG. 1, which is a schematic diagram showing a display panel P in accordance with an embodiment of the present disclosure. The display panel P includes a pixel array substrate 100, an opposite substrate 200, and a display medium layer 300. The opposite substrate 200 may include common components such as a glass substrate, a color filter, a polarizer or an alignment film. The display medium layer 300 is placed between the pixel array substrate 100 and the opposite substrate 200.

In some embodiments, the display medium layer 300 is an electrophoretic display material layer and includes multiple colored electrophoretic particles. The pixel array substrate 100 and the opposite substrate 200 may be a substrate including a transparent conductive film. The electric field between the pixel array substrate 100 and the opposite substrate 200 can be varied by providing potentials to the transparent conductive substrates therein, causing colored electrophoretic particles to move towards the pixel array substrate 100 or the opposite substrate 200. In this way, the display panel P may show pictures with different grayscales.

In other embodiments, the display medium layer 300 may be a liquid crystal material layer including multiple liquid crystal molecules. The electric field between the pixel array substrate 100 and the opposite substrate 200 can be varied by providing potentials to the transparent conductive substrates therein, causing liquid crystal molecules to twist to different degrees. In this way, the display panel P may show pictures with different grayscales.

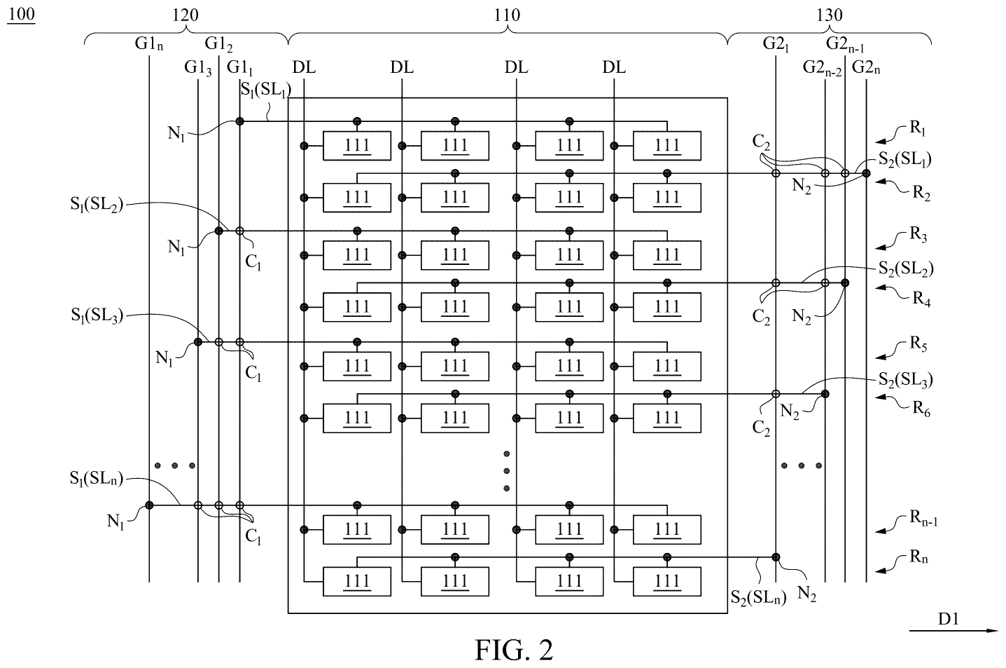

Reference is made to FIG. 2, which is a schematic diagram showing a pixel array substrate 100 in accordance with an embodiment of the present disclosure. The pixel array substrate 100 has a display area 110, a first peripheral region 120, and a second peripheral region 130, and the first peripheral region 120 and the second peripheral region 130 are located on opposite sides of the display area 110 respectively. The pixel array substrate 100 includes several pixel circuits 111, several first conductive lines G1₁-G1ₙ, several second conductive lines G2₁-G2ₙ, and several pairs of scan lines SL₁-SLₙ.

The pixel circuits 111 are placed at the display area 110, and the pixel circuits 111 arranged along a first direction D1 form several pixel columns R₁-Rₙ. The first conductive lines G1₁-G1ₙ are placed at the first peripheral region 120, and the second conductive lines G2₁-G2ₙ are placed at the second peripheral region 130. Each of the pairs of scan lines SL₁-SLₙ includes a first scan line S₁ and a second scan line S₂.

Each of the first scan lines S₁ is electrically connected to a corresponding one of the first conductive lines G1₁-G1ₙ through a first node N₁, and extends to the display area 110 from the first node N₁ to electrically connect a corresponding one of first pixel columns R₁, R₃, R₅ . . . , and Rₙ₋₁ of the pixel columns R₁-Rₙ. Each of the second scan lines S₂ is electrically connected to a corresponding one of the second conductive lines G2₁-G2ₙ through a second node N₂, and extends to the display area 110 from the second node N₂ to electrically connect a corresponding one of second pixel columns R₂, R₄, R₆ . . . , and Rₙ of the pixel columns R₁-Rₙ.

In each of the pairs of scan lines SL₁-SLₙ, the number of total cross-capacitances C_{T} is defined as a sum of the number of first cross-capacitances C₁ formed by the first scan line S₁ crossing the first conductive lines G1₁-G1ₙ and the number of second cross-capacitances C₂ formed by the second scan line S₂ crossing the second conductive lines G2₁-G2ₙ. The total cross-capacitances C_{T} for the second pair of scan lines S_{L2} is the same as the total cross-capacitances C_{T} for the first pair of scan lines S_{L1}. The total cross-capacitances C_{T} for the third pair of scan lines SL₃ is the same as the total cross-capacitances C_{T} for the first pair of scan lines S_{L1}. By analogy, as more pairs of scan lines SL have the same total cross-capacitances C_{T} as the first pair of scan lines SL₁, the brightness of the display becomes more uniform. In one embodiment of the disclosure, more than 80% of the pairs of scan lines SL in the display have the same number of the total cross-capacitances C_{T}. In another embodiment of the disclosure, the number of the total cross-capacitances C_{T} is the same for each of the pairs of scan lines SL₁-SLₙ. The designer can adjust the number of the total cross-capacitances C_{T} for each of the pairs of scan lines SL₁-SLₙ according to their needs.

Taking the first pair of scan lines SL₁ as an example, the first scan line S₁ is electrically connected to the first conductive line G1₁ and does not cross any of the first conductive lines G12-G1ₙ before being electrically connected to the pixel circuits 111 of the first pixel column R₁. Thus, the number of the first cross-capacitances C₁ formed is 0. The second scan line S₂ is electrically connected to the second conductive line G2ₙ and crosses the second conductive lines G2₁-G2ₙ₋₁ before being electrically connected to the pixel circuits 111 of the second pixel column R₂, thereby forming (n−1) second cross-capacitances C₂. Thus, the total cross-capacitances C_{T} for the first pair of scan lines SL₁ is 0+ (n−1)=(n−1).

Taking the last pair of scan lines SLₙ as an example, the first scan line S₁ is electrically connected to the first conductive line Gin and crosses the first conductive lines G1₁-G1ₙ₋₁ before being electrically connected to the pixel circuits 111 of the first pixel column Rₙ₋₁, thereby forming (n−1) first cross-capacitances C₁. The second scan line S₂ is electrically connected to the second conductive line G2₁ and does not cross any of the second conductive lines G22-G2ₙ before being electrically connected to the pixel circuits 111 of the second pixel column Rₙ. Therefore, the number of the second cross-capacitances C₂ formed is 0. The total cross-capacitances C_{T} for the last pair of scan lines SLₙ is (n−1)+0=(n−1).

As can be easily understood from the examples of the first pair of scan lines SL₁ and the last pair of scan lines SLₙ, the number of the total cross-capacitances C_{T} (i.e., the number of the first cross-capacitances C₁ plus the number of the second cross-capacitances C₂) are the same for each of the other pairs of scan lines SL₂ to SLₙ₋₁ (i.e., all of them are n−1). By having the same total cross-capacitances C_{T} for each of the pairs of scan lines SL₁-SLₙ, the problem of uneven brightness of pixel columns caused by the difference in the total cross-capacitances C_{T} of different pairs of scan lines SL₁-SLₙ may be effectively improved, and the display quality may be enhanced.

In the embodiment of the disclosure, the first scan line S₁ and the second scan line S₂ of the pairs of scan lines SL₁-SLₙ are interleaved with each other. In other words, the first scan lines S₁ are electrically connected to the pixel circuits 111 of the first pixel columns R₁, R₃, R₅ . . . , and Rₙ₋₁, and the second scan lines S₂ are electrically connected to the pixel circuits 111 of the second pixel columns R₂, R₄, R₆ . . . , and Rₙ, so that these first scan lines S₁ and second scan lines S₂ are interleaved with each other.

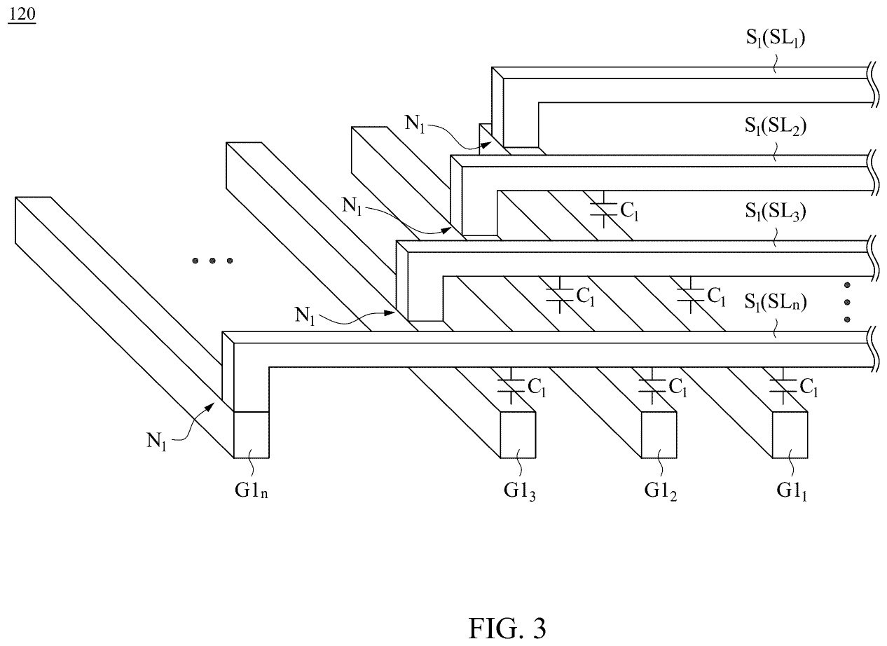

Reference is made to FIG. 3, which is an enlarged schematic diagram showing first conductive lines G1₁-G1ₙ and first scan lines S₁ at the first peripheral region 120 in accordance with an embodiment of the present disclosure. As mentioned before, the first scan line S₁ of each of the pairs of scan lines SL₁-SLₙ is electrically connected to a corresponding first conductive line G1₁-G1ₙ through the first node N₁, and extends in a direction from the first node N₁ towards the display area 110 (not shown in FIG. 3). As can be seen from FIG. 3, in addition to the first conductive line to which the first node N₁ is electrically connected, the first scan line S₁ crosses the other first conductive lines and forms several first cross-capacitances C₁ with each of them.

As shown in FIG. 2 and FIG. 3, among the pairs of scan lines SL₁-SLₙ, there is an increasing trend in the number of first cross-capacitances C₁ formed across the first conductive lines G1₁-G1ₙ from the first scan line S₁ of the first pair of scan lines SL₁ to the first scan line S₁ of the last pair of scan lines SLₙ. Specifically, the number of first cross-capacitances C₁ formed by the first scan line S₁ of the first pair of scan lines SL₁ is 0, the number of first cross-capacitances C₁ formed by the first scan line S₁ of the second pair of scan lines SL₂ is increased to 1, the number of first cross-capacitances C₁ formed by the first scan line S₁ of the third pair of scan lines SL₃ is increased to 2, and so on until the number of first cross-capacitances C₁ formed by the first scan line S₁ of the last pair of scan lines SLₙ is increased to n−1.

Although an enlarged schematic diagram of the second conductive lines G2₁-G2ₙ and the second scan lines S₂ at the second peripheral region 130 is not shown herein, it should be understood by a person who skilled in the art from FIG. 3 that, in addition to the second conductive line to which the second node N₂ is electrically connected, each of the second scan lines S₂ crosses the other second conductive lines and forms several second cross-capacitances C₂ with each of them.

In addition, with respect to the first scan line S₁, there is a decreasing trend in the number of second cross-capacitances C₂ formed across the second conductive lines G2₁-G2ₙ from the second scan line S₂ of the first pair of scan lines SL₁ to the second scan line S₂ of the last pair of scan lines SLₙ. Specifically, the number of second cross-capacitances C₂ formed by the second scan line S₂ of the first pair of scan lines SL₁ is n−1, the number of second cross-capacitances C₂ formed by the second scan line S₁ of the second pair of scan lines SL₂ is decreased to n−2, the number of second cross-capacitances C₂ formed by the second scan line S₂ of the third pair of scan lines SL₃ is decreased to n−3, and so on until the number of second cross-capacitances C₂ formed by the second scan line S₂ of the last pair of scan lines SLₙ is increased to 0. In this way, the number of the total cross-capacitances C_{T} of each of the pairs of scan lines SL₁-SLₙ are all the same (i.e., all of them are n−1).

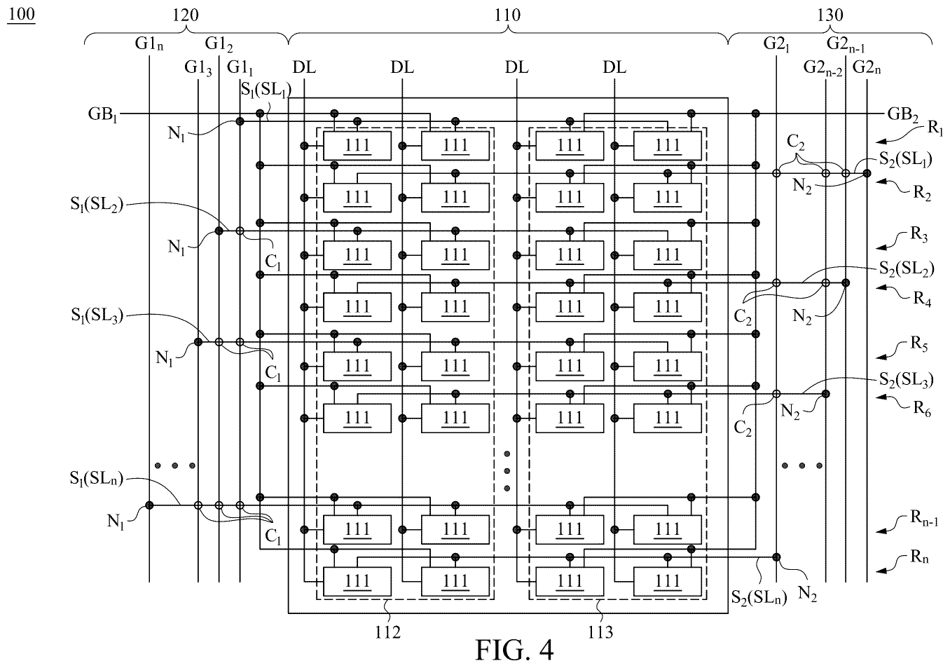

Reference is made to FIG. 4, which is a schematic diagram showing a pixel array substrate 100 having several display blocks in accordance with an embodiment of the present disclosure. The display area 110 has a first display block 112 and a second display block 113, and the pixel circuits 111 are placed at the first display block 112 and the second display block 113 respectively. In such an embodiment, the pixel array substrate 100 further includes a first block selection line GB₁ and a second block selection line GB₂.

The first block selection line GB₁ is placed at the first peripheral region 120 and corresponds to the first display block 112 to electrically connect to the pixel circuits 111 placed at the first display block 112. Specifically, each pixel circuit 111 in the first display block 112 is electrically connected to the first scan line S₁ or the second scan line S₂ of one of the pairs of scan lines SL₁-SLₙ, the first block selection line GB₁, and a data line DL.

The second block selection line GB₂ is placed at the second peripheral region 130 and corresponds to the second display block 113 to electrically connect the pixel circuits 111 placed at the second display block 113. Specifically, each pixel circuit 111 in the second display block 113 is electrically connected to the first scan line S₁ or the second scan line S₂ of one of the pairs of scan lines SL₁-SLₙ, the second block selection line GB₂, and the data line DL.

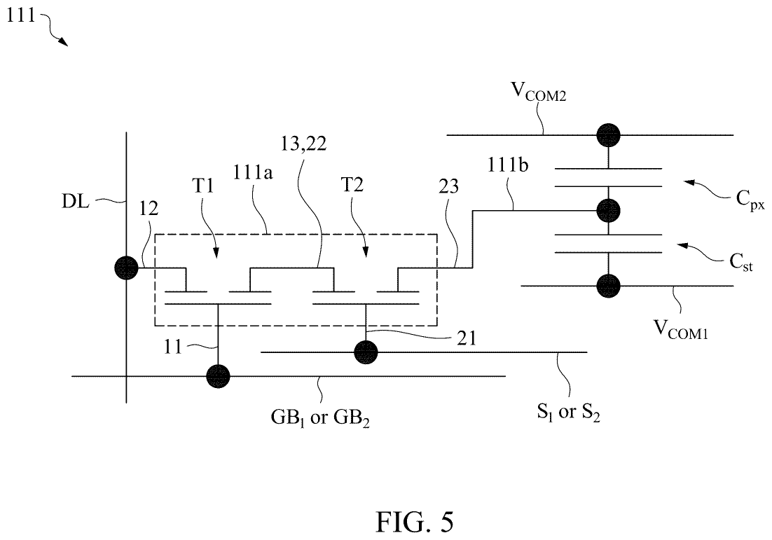

Reference is made to FIG. 5, which is a schematic diagram showing a pixel circuit 111 in accordance with an embodiment of the present disclosure. As shown in FIG. 5, the pixel circuit 111 includes an AND gate circuit 111a and a pixel electrode 111b. The AND gate circuit 111a is electrically connected to the pixel electrode 111b, and includes a first transistor T1 and a second transistor T2.

A first terminal (or control terminal) 11 of the first transistor T1 is electrically connected to the first block selection line GB₁ or the second block selection line GB₂, and a second terminal (or source/drain terminal) 12 of the first transistor T1 is electrically connected to the data line DL. A first terminal (or control terminal) 21 of the second transistor T2 is electrically connected to the first scan line S₁ or the second scan line S₂ of one of the pairs of scan lines SL₁-SLₙ, a second terminal (or source/drain terminal) 22 of the second transistor T2 is electrically connected to a third terminal (or drain/source terminal) 13 of the first transistor T1, and a third terminal (or drain/source terminal) 23 of the second transistor T2 is electrically connected to the pixel electrode 111b. In the embodiments of the present disclosure, the first transistor T1 and the second transistor T2 may be N-type transistors or P-type transistors, and the present disclosure is not limited thereto.

With respect to the pixel circuits 111 in the first display block 112, the first terminal 11 of the first transistor T1 is electrically connected to the first block selection line GB₁, and the first terminal 21 of the second transistor T2 is electrically connected to the first scan line S₁ or the second scan line S₂ of the pairs of scan lines SL₁-SLₙ (depending on whether the pixel circuits 111 in the first display block 112 are located in the first pixel columns R₁, R₃, R₅ . . . , and Rₙ₋₁, or in the second pixel columns R₂, R₄, R₆ . . . , and Rₙ).

When the pixel circuits 111 of the first pixel columns R₁, R₃, R₅ . . . , and Rₙ₋₁ in the first display block 112 receives conduction signals from both the first block selection line GB₁ and the first scan line S₁, the first transistor T1 and the second transistor T2 of the pixel circuits 111 will conduct accordingly, so that the data of the data line DL can be transmitted to the pixel electrode 111b. In other words, when the pixel circuits 111 receive the conduction signal of only one of the first block selection line GB₁ and the first scan line S₁, the side that does not receive the conduction signal cannot turn on the corresponding transistor, so that the data of the data line DL cannot be transmitted to the pixel electrode 111b.

Similarly, when the pixel circuits 111 of the second pixel columns R₂, R₄, R₆ . . . , and Rₙ of the first display block 112 receives conduction signals from the first block selection line GB₁ and the second scan line S₂, the first transistor T1 and the second transistor T2 of the pixel circuit 111 will conduct accordingly, so that the data of the data line DL can be transmitted to the pixel electrode 111b. In other words, when the pixel circuits 111 receive the conduction signal of only one of the first block selection line GB₁ and the second scan line S₂, the side that does not receive the conduction signal cannot turn on the corresponding transistor, so that the data of the data line DL cannot be transmitted to the pixel electrode 111b.

With respect to the pixel circuits 111 in the second display block 113, the first terminal 11 of the first transistor T1 is electrically connected to the second block selection line GB₂, and the first terminal 21 of the second transistor T2 is electrically connected to the first scan line S₁ or the second scan line S₂ of the pairs of scan lines SL₁-SLₙ (depending on whether the pixel circuits 111 in the second display block 113 are located in the first pixel columns R₁, R₃, R₅ . . . , and Rₙ₋₁, or in the second pixel columns R₂, R₄, R₆ . . . , and Rₙ).

When the pixel circuits 111 of the first pixel columns R₁, R₃, R₅ . . . , and Rₙ₋₁ in the second display block 113 receives conduction signals from both the second block selection line GB₂ and the first scan line S₁, the first transistor T1 and the second transistor T2 of the pixel circuits 111 will conduct accordingly, so that the data of the data line DL can be transmitted to the pixel electrode 111b. In other words, when the pixel circuits 111 receive the conduction signal of only one of the second block selection line GB₂ and the first scan line S₁, the side that does not receive the conduction signal cannot turn on the corresponding transistor, so that the data of the data line DL cannot be transmitted to the pixel electrode 111b.

Similarly, when the pixel circuits 111 of the second pixel columns R₂, R₄, R₆ . . . , and Rₙ of the second display block 113 receives conduction signals from the second block selection line GB₂ and the second scan line S₂, the first transistor T1 and the second transistor T2 of the pixel circuits 111 will conduct accordingly, so that the data of the data line DL can be transmitted to the pixel electrode 111b. In other words, when the pixel circuits 111 receive the conduction signal of only one of the second block selection line GB₂ and the second scan line S₂, the side that does not receive the conduction signal cannot turn on the corresponding transistor, so that the data of the data line DL cannot be transmitted to the pixel electrode 111b.

In the embodiment of the disclosure, the pixel circuit 111 further includes a first common electrode V_{COM1} and a second common electrode V_{COM2}. The first common electrode V_{COM1} forms a storage capacitance Cₛₜ between the first common electrode V_{COM1} and the pixel electrode 111b, and the second common electrode V_{COM2} forms a pixel capacitance Cₚₓ between the second common electrode V_{COM2} and the pixel electrode 111b. In some embodiments, the first common electrode V_{COM1} is a common reference voltage for the pixel array substrate 100, and the second common electrode V_{COM2} is a common reference voltage for the opposite substrate 200.

In summary, the pixel array substrate and the display panel of the present disclosure have the same number of total cross-capacitances formed by each pair of scan lines, resulting from the arrangement of the first scan line and the second scan line in each pair of scan lines. In this way, the present disclosure may effectively reduce the problem of uneven brightness caused by the capacitive coupling effect between the adjacent first scan line and the second scan line, so that the pixel array substrate and the display panel have better display quality.

Although the description provided above is of various embodiments of the disclosure, this is not intended to limit the scope of the disclosure. Those skilled in the art may make various modifications without departing from the spirit and scope of the disclosure. Therefore, the scope of protection of the present disclosure is determined by the following claims.

What is claimed is:

1. A pixel array substrate having a display area, a first peripheral region, and a second peripheral region, wherein the first peripheral region and the second peripheral region are located at two sides of the display area, the pixel array substrate comprising:
a plurality of pixel circuits placed at the display area and forming a plurality of pixel columns;
first conductive lines placed at the first peripheral region;
second conductive lines placed at the second peripheral region; and
a plurality of pairs of scan lines, wherein each of the pairs of scan lines comprises:
a first scan line connected to a corresponding one of the first conductive lines through a first node, and extending to the display area from the first node for connecting a first pixel column of the pixel columns; and
a second scan line connected to a corresponding one of the second conductive lines through a second node, and extending to the display area from the second node for connecting a second pixel column of the pixel columns;
wherein a sum of number of cross-capacitances formed by the first scan line crossing the first conductive lines and number of cross-capacitances formed by the second scan line crossing the second conductive lines are the number of total cross-capacitances, and number of the total cross-capacitances is the same for each of the pairs of scan lines.

2. The pixel array substrate of claim 1, wherein the display area has a first display block and a second display block, the plurality of pixel circuits are placed at the first display block and the second display block, and the pixel array substrate further comprising:
a first block selection line placed at the first peripheral region and corresponding to the first display block, wherein the first block selection line is electrically connected to the plurality of pixel circuits placed at the first display block; and
a second block selection line placed at the second peripheral region and corresponding to the second display block, wherein the second block selection line is electrically connected to the plurality of pixel circuits placed at the second display block.

3. The pixel array substrate of claim 2, wherein one of the plurality of pixel circuits is electrically connected to the first scan line or the second scan line of one of the pairs of scan lines, one of the first block selection line and the second block selection line, and a data line.

4. The pixel array substrate of claim 3, wherein the one of the plurality of pixel circuits comprises:
an AND gate circuit, comprising:
a first transistor, a first terminal of the first transistor is electrically connected to one of the first block selection line and the second block selection line, and a second terminal of the first transistor is electrically connected to the data line; and
a second transistor, a first terminal of the second transistor is electrically connected to the first scan line or the second scan line of the one of the pairs of scan lines, and a second terminal of the second transistor is electrically connected to a third terminal of the first transistor; and
a pixel electrode electrically connected to a third terminal of the second transistor.

5. The pixel array substrate of claim 1, wherein the first peripheral region and the second peripheral region are located on opposite sides of the display area.

6. The pixel array substrate of claim 1, wherein the first scan line and the second scan line of the pairs of scan lines are interleaved with each other.

7. The pixel array substrate of claim 1, wherein the number of cross-capacitances formed by the first scan line crossing the first conductive lines of the first one of the pairs of scan lines to the number of cross-capacitances formed by the first scan line crossing the first conductive lines of the last one of the pairs of scan lines are in an ascending order.

8. The pixel array substrate of claim 1, wherein the number of cross-capacitances formed by the second scan line crossing the second conductive lines of the first one of the pairs of scan lines to the number of cross-capacitances formed by the second scan line crossing the second conductive lines of the last one of the pairs of scan lines are in a descending order.

9. A display panel, comprising:
a pixel array substrate having a display area, a first peripheral region, and a second peripheral region, wherein the first peripheral region and the second peripheral region are located at two sides of the display area, the pixel array substrate comprising:
a plurality of pixel circuits placed at the display area and forming a plurality of pixel columns;
first conductive lines placed at the first peripheral region;
second conductive lines placed at the second peripheral region; and
a plurality of pairs of scan lines, wherein each of the pairs of scan lines comprises:
a first scan line connected to a corresponding one of the first conductive lines through a first node, and extending to the display area from the first node for connecting a first pixel column of the pixel columns; and
a second scan line connected to a corresponding one of the second conductive lines through a second node, and extending to the display area from the second node for connecting a second pixel column of the pixel columns;
wherein a sum of number of cross-capacitances formed by the first scan line crossing the first conductive lines and number of cross-capacitances formed by the second scan line crossing the second conductive lines are the number of total cross-capacitances, and number of the total cross-capacitances is the same for each of the pairs of scan lines;
an opposite substrate; and
a display medium layer placed between the pixel array substrate and the opposite substrate.

10. The display panel of claim 9, wherein the display medium layer is an electrophoretic display material layer.

11. The display panel of claim 9, wherein the display medium layer is a liquid crystal material layer.

12. The display panel of claim 9, wherein the display area has a first display block and a second display block, the plurality of pixel circuits are placed at the first display block and the second display block, and the pixel array substrate further comprising:
a first block selection line placed at the first peripheral region and corresponding to the first display block, wherein the first block selection line is electrically connected to the plurality of pixel circuits placed at the first display block; and
a second block selection line placed at the second peripheral region and corresponding to the second display block, wherein the second block selection line is electrically connected to the plurality of pixel circuits placed at the second display block.

13. The display panel of claim 12, wherein each of the plurality of pixel circuits comprises:
an AND gate circuit, comprising:
a first transistor, a first terminal of the first transistor is electrically connected to one of the first block selection line and the second block selection line, and a second terminal of the first transistor is electrically connected to a data line; and
a second transistor, a first terminal of the second transistor is electrically connected to the first scan line or the second scan line of the one of the pairs of scan lines, and a second terminal of the second transistor is electrically connected to a third terminal of the first transistor; and
a pixel electrode electrically connected to a third terminal of the second transistor.

14. The display panel of claim 13, wherein each of the plurality of pixel circuits further comprises:
a storage capacitance, a first terminal of the storage capacitance connects the pixel electrode, and a second terminal of the storage capacitance connects a first common electrode; and
a pixel capacitance, a first terminal of the pixel capacitance connects a second common electrode, and a second terminal of the pixel capacitance connects the pixel electrode.

15. The display panel of claim 14, wherein the first common electrode is a common reference voltage for the pixel array substrate, and the second common electrode is a common reference voltage for the opposite substrate.

16. The display panel of claim 9, wherein the first scan line and the second scan line of the pairs of scan lines are interleaved with each other.
